(19) United States
(12) Patent Application Publication
(10) Pub. No.: US 2026/0339523 A1
(43) Pub. Date: Oct. 29, 2026

(54) MEMORY SYSTEMS, DEVICES, CONTROLLERS, CONTROL METHODS AND STORAGE MEDIA

(71) Applicant: Yangtze Memory Technologies Co., Ltd., Wuhan (CN)

(72) Inventors: Haofei Du, Wuhan (CN); Tao Xiong, Wuhan (CN)

(21) Appl. No.: 19/287,373

(22) Filed: Jul. 31, 2025

(30) Foreign Application Priority Data
Apr. 28, 2025 (CN) 202510549686.8

(51) Int. Cl. G06F 3/06

(52) U.S. Cl. CPC G06F 3/0617; G06F 3/0653; G06F 3/0679

(57) ABSTRACT

An example memory system comprises: a memory device comprising a plurality of memory blocks; and a memory controller configured to: obtain a first voltage offset group of a first memory block in response to the memory system being powered on after powered down; and adjust a retention time corresponding to at least one memory block in the memory device based on the first voltage offset group and a second voltage offset group, wherein the second voltage offset group is a voltage offset group of the first memory block obtained before the memory system is powered down. The power failure time of the memory system can be predicted through the first voltage offset group and the second voltage offset group, and the power failure time is added to the retention time of the memory block.

### CROSS-REFERENCE TO RELATED APPLICATIONS

This application claims priority to and the benefit of Chinese Patent Application 202510549686.8, filed on Apr. 28, 2025, which is hereby incorporated by reference in its entirety.

### FIELD OF TECHNOLOGY

The present disclosure relates to the field of memory technologies, and in particular, to memory systems, devices, controllers, control methods, and storage media.

### BACKGROUND

A retention time of a solid state drive (SSD) refers to a time for which data has been kept in a memory block after being programmed, and as the retention time increases, the reliability of the data is reduced, so it is necessary to take corresponding actions to ensure the reliability of the data.

### BRIEF DESCRIPTION OF THE DRAWINGS

In order to more clearly illustrate the technical solutions in the examples of the present disclosure, the accompanying drawings that need to be used in the description of the examples are briefly described below, and the accompanying drawings in the following description are merely some examples of the present disclosure, and for those of ordinary skill in the art, other accompanying drawings may be obtained based on these accompanying drawings without falling outside the scope of the present disclosure.

FIG. 1 is a schematic diagram of a computer system according to some examples of the present disclosure.

FIG. 2 is a schematic structural diagram of a memory system according to the present disclosure.

FIG. 3 is a schematic structural diagram of a memory device according to some examples of the present disclosure.

FIG. 4 is a schematic circuit diagram of a memory device according to some examples of the present disclosure.

FIG. 5 is a schematic diagram of a memory system according to some examples of the present disclosure.

FIG. 6 is a schematic diagram of a TLC programming threshold voltage distribution according to an example of the present disclosure.

FIG. 7 is a schematic structural diagram of a memory controller according to some examples of the present disclosure.

FIG. 8 is a schematic diagram of a computer system according to some examples of the present disclosure.

FIG. 9 is a flowchart of a control method of a memory system according to some examples of the present disclosure.

FIG. 10 is a flowchart of another control method of a memory system according to some examples of the present disclosure.

### DETAILED DESCRIPTION

Power failure time of an SSD should be considered within a retention time, and how to predict the power failure time of the SSD becomes an urgent problem to be solved. Examples of the present disclosure are described in detail below with reference to the accompanying drawings.

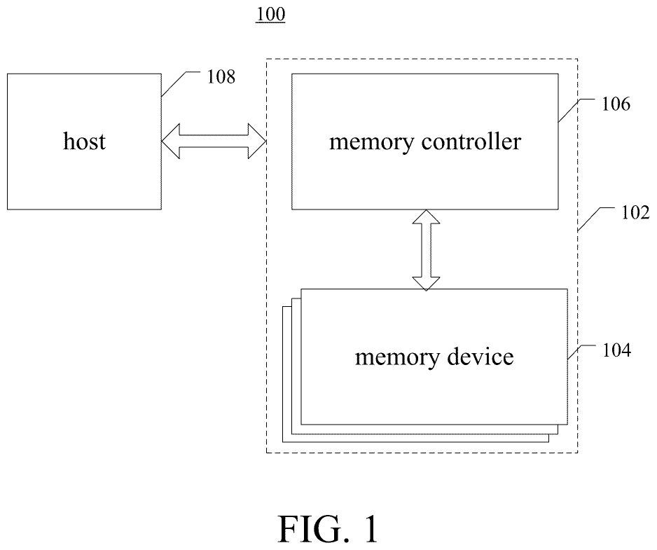

The computer system according to some examples of the present disclosure may comprise a host and a memory system. FIG. 1 is a schematic diagram of a computer system according to some examples of the present disclosure. As shown in FIG. 1, the system 100 comprises a memory system 102 and a host 108 coupled to the memory system 102. The memory system 102 comprises a memory device 104, and a memory controller 106 coupled to the memory device 104 and configured to control the memory device 104.

In some examples, the system 100 may be integrated into various types of electronic devices. The electronic device may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or the like.

The memory system 102 may be implemented as a memory system of a type such as a universal flash storage (UFS) or a solid state disk (SSD). In some examples of the present disclosure, taking an example in which the memory system 102 is implemented as an SSD for description.

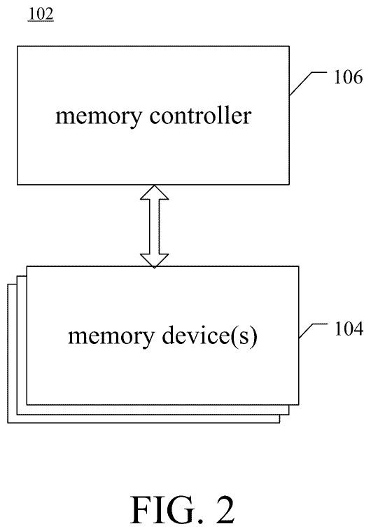

As another example, FIG. 2 is a schematic structural diagram of a memory system according to the present disclosure. As shown in FIG. 2, the memory system 102 may be a solid state drive (SSD), and the memory system 102 comprises a memory device 104 and a memory controller 106. Memory system 102 may also comprise a connector coupling the memory system 102 with the host 108.

In some examples, the memory device 104 may be implemented as a NAND flash, such as a three-dimensional (3-Dimension, 3D) NAND flash. The structure of the memory device 104 is explained below.

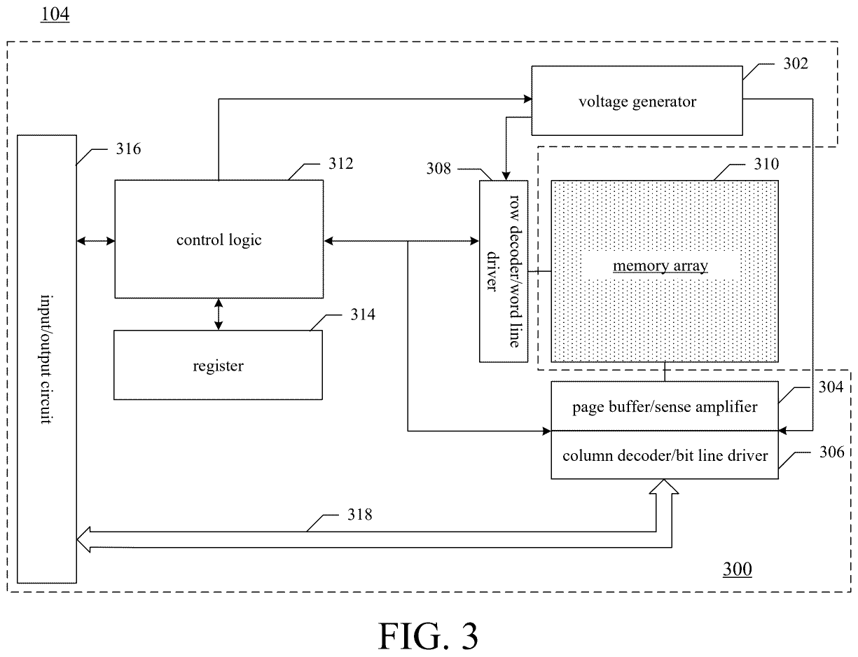

FIG. 3 is a schematic structural diagram of a memory device according to some examples of the present disclosure. As shown in FIG. 3, the memory device 104 comprises a peripheral circuit 300 and a memory array 310.

The peripheral circuit 300 is configured to write data into the memory array 310 and read data from the memory array 310. The peripheral circuit 300 comprises a voltage generator 302, a page buffer/sense amplifier 304, a column decoder/bit line (BL) driver 306, a row decoder/word line (WL) driver 308, control logic 312, a register 314, an input/output circuit 316, and a data bus 318. It should be understood that in some examples, additional peripheral circuits not shown in FIG. 3 may also be included.

The voltage generator 302 may be configured to be controlled by the control logic 312 and generate word line voltages (e.g., read voltages, program voltages, pass voltages, local voltages, verify voltages, etc.), bit line voltages, and source line voltages to be supplied to the memory array 310.

The page buffer/sense amplifier 304 may be configured to read data from and program (write) data to the memory array 310 according to control signals from the control logic 312. In one example, the page buffer/sense amplifier 304 may store a page of programming data (write data) to be programmed into one page of the memory array 310. In another example, the page buffer/sense amplifier 304 may perform a program verify operation to ensure that data has been correctly programmed into the memory cells coupled to the selected word line. In yet another example, the page buffer/sense amplifier 304 may also sense a low power signal from the bit line representing a data bit stored in the memory cell, and amplify the small voltage swing to an identifiable logic level in a read operation.

Column decoder/bit line driver 306 may be configured to be controlled by control logic 312 and select one or more memory strings (e.g., NAND memory strings) by applying a bit line voltage generated from voltage generator 302.

The row decoder/word line driver 308 may be configured to be controlled by the control logic 312 and select/deselect blocks of the memory array 310 and select/deselect the word lines of the block. The row decoder/word line driver 308 may also be configured to drive a word line using a word line voltage (VWL) generated from the voltage generator 302. In some examples, the row decoder/word line driver 308 may also select/deselect and drive the source select gate line and the drain select gate line. For example, the row decoder/word line driver 308 is configured to perform an erase operation on memory cells coupled to the selected word line(s).

The control logic 312 may be coupled to other components of each peripheral circuit described above and configured to control operation of other components of each peripheral circuit.

The register 314 may be coupled to the control logic 312 and comprise status registers, command registers, and address registers for storing status information, command operation codes (OP codes), and command addresses for controlling operation of each peripheral circuit.

The input/output circuit 316 may be coupled to the control logic 312 and act as a control buffer to buffer control commands received from a host (not shown) and relay them to the control logic 312 and buffer status information received from the control logic 312 and relay it to the host. The input/output circuit 316 may also be coupled to the column decoder/bit line driver 306 via a data bus 318 and act as a data input/output interface and a data buffer to buffer data and relay it to the memory array 310, or relay or buffer data from the memory array 310.

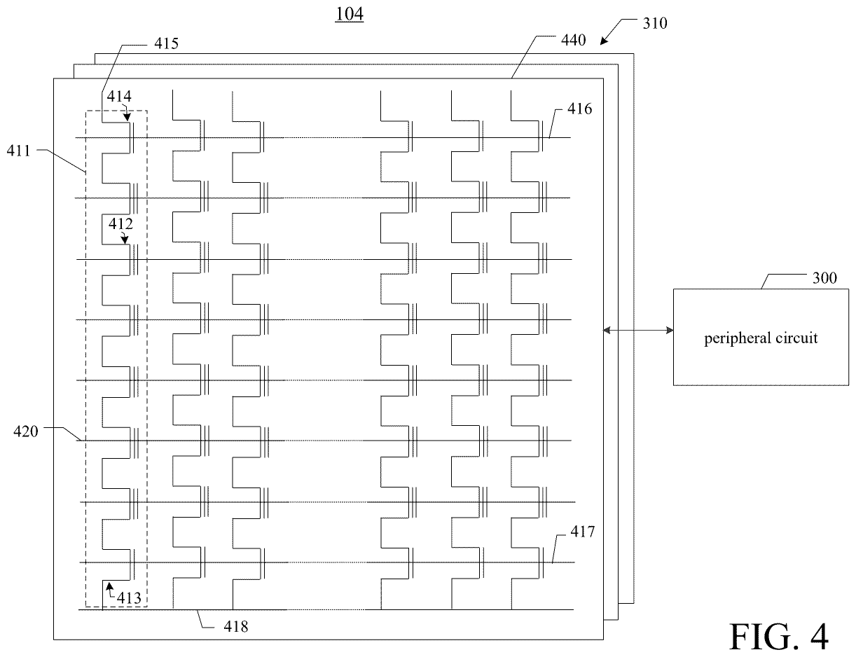

FIG. 4 is a schematic circuit diagram of a memory device according to some examples of the present disclosure. As shown in FIG. 4, the memory device 104 comprises:
a memory array 310 comprising a plurality of memory cell rows,
a plurality of word lines 420 coupled to a plurality of memory cell rows, respectively, and
a peripheral circuit 300 coupled to the plurality of word lines 420 and configured to perform operations such as programming (e.g., writing data) or reading data on selected ones of the plurality of memory cell rows, wherein the selected memory cell rows are the memory cell rows coupled to the selected word lines for performing operations such as programming or reading data.

The memory array 310 may be a flash memory array (e.g., a NAND memory array). The memory array 310 comprises a plurality of memory strings 411 arranged in an array, wherein each memory string 411 extends vertically above a substrate (not shown). In some examples, each memory string 411 comprises a plurality of memory cells 412 coupled in series and vertically stacked. The memory cell 412 comprises, but is not limited to, a Single-Level Cell (SLC), a Multi-Level Cell (MLC), a Trinary-Level Cell (TLC), and a Quad-Level Cell (QLC), etc.

As shown in FIG. 4, each memory string 411 may further comprise a source select gate (SSG) 413 at the bottom and a drain select gate (DSG) 414 at the top. The source select gate is also referred to as a lower select transistor, a bottom select gate (BSG), or a source select transistor, and the drain select gate is also referred to as an upper select transistor, a top select gate (TSG), or a drain select transistor. The source select gate 413 and the drain select gate 414 may be configured to activate the selected memory string 411 during read and program operations.

In some examples, the drain select gate 414 of each memory string 411 is coupled to respective bit line 415 from which data may be read or written via an output bus (not shown).

In some examples, each memory string 411 is configured to apply a select voltage (e.g., higher than a threshold voltage of a transistor having a drain select gate 414) or a deselect voltage (e.g., 0V) to a respective drain select gate 414 through one or more DSG lines 416. Additionally or alternatively, in some examples, each memory string 411 is configured to be selected or deselected by applying a select voltage (e.g., higher than a threshold voltage of a transistor having a source select gate 413) or a deselect voltage (e.g., 0V) to a respective source select gate 413 through one or more SSG lines 417.

As shown in FIG. 4, the memory string 411 may be organized into a plurality of blocks 440, and for any one of the plurality of blocks 440, there may be one source line (SL) 418, and the sources of all memory strings 411 in the block 440 are coupled through the source line 418, which is also referred to as a common source line or an array common source (ACS).

The source line 418 may be configured to be grounded, so as to subsequently ground the source of each memory cell of the memory string in the block 440 in some operations. In some examples, in some other operations, the source of each memory cell of the memory string in the block 440 may also be connected to a high voltage through the source line 418.

Each block 440 is a basic data unit for an erase operation, that is, all memory cells 412 on the same block 440 are simultaneously erased. To erase the memory cells 412 in the selected block, the source lines coupled to the selected block may be biased with erase voltages (Vers), such as a high positive voltage (20V or higher).

It should be understood that in other examples, the erase operation may be performed at a half-block level, at a quarter-block level, or at a level of any suitable number of blocks or any suitable fraction of a memory block.

As shown in FIG. 4, the same layer of memory cells 412 of adjacent memory strings 411 in the same block 440 may be coupled by word lines 420, wherein the word lines 420 are configured to select which layer of the memory cells 412 in block 440 is affected by read and program operations.

In some examples, each word line 420 is coupled to a page to which the memory cell 412 belongs, wherein the page is a basic data unit for a program operation. The size of the page may be related to the number of memory strings 411 in one block 440 coupled by the word line 420. Each word line 420 may be coupled on a control gate (e.g., gate electrode) of each memory cell 412 in a respective page. It can be understood that one memory cell row is a plurality of memory cells 412 located on the same page.

It should be noted that the same layer of memory cells in one block 440 correspond to the same word line, but the same layer of memory cells may be divided into one or more pages. That is, one word line may be coupled to one or more pages.

Peripheral circuit 300 may be coupled to memory array 310 through bit lines 415, word lines 420, source lines 418, SSG lines 417, and DSG lines 416. Peripheral circuit 300 may comprise any suitable analog, digital, and mixed-signal circuit for facilitating operation of memory array 310 by applying voltage and/or current signals to memory cell 412 and sensing voltage and/or current signals from memory cell 412 via bit line 415, word line 420, source line 418, SSG line 417, and DSG line 416.

In a memory system, such as a solid state drive (SSD), power failure means that the SSD loses external power supply. A retention time of the SSD refers to a time for which data has been kept in a memory block after being programmed, and as the retention time increases, electrons in the storage layer of the memory cell may be lost under the effect of the intrinsic electric field, resulting in a decrease in the reliability of the data, and a corresponding action needs to be performed to ensure the reliability of the data, for example, the data is moved from the current memory block to another memory block.

The power failure time of the SSD should also be considered within the retention time, and how to predict the power failure time of the SSD becomes an urgent problem to be solved.

Based on this, the present disclosure provides a memory system 102, which can add the power failure time to the retention time of the memory block, and adjust the retention time of the memory block, which improves the accuracy of recording the retention time of the memory block, thereby improving the timeliness and accuracy of the memory system 102 when performing the reliability actions on the memory block based on the retention time, and improving the running stability of the memory system 102.

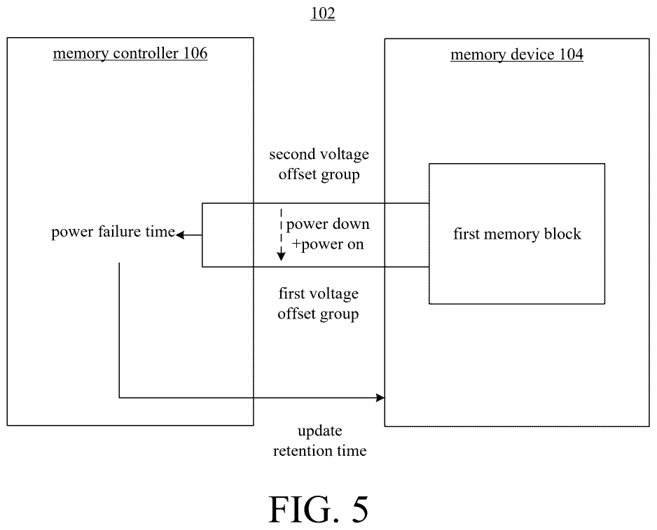

FIG. 5 is a schematic diagram of a memory system 102 according to some examples of the present disclosure. As shown in FIG. 5, the memory system 102 comprises a memory device 104 and a memory controller 106, wherein the memory device 104 comprises a plurality of memory blocks. In some examples, the memory system 102 comprises a solid state drive SSD, a universal flash memory (UFS), an embedded multimedia card (eMMC), and the like. In some examples, in some examples of the present disclosure, taking an example in which the memory device 104 comprises a Trinary-Level Cell (TLC) for description, and the memory device 104 may further comprise a Multi-Level Cell (MLC), a Quad-Level Cell (QLC), and the like, which is not limited in some examples of the present disclosure.

The memory controller 106 is configured to: obtain a first voltage offset group of a first memory block in response to the memory system 102 being powered on after powered down; and adjust a retention time corresponding to at least one memory block in the memory device 104 based on the first voltage offset group and a second voltage offset group, wherein the second voltage offset group is a voltage offset group of the first memory block obtained before the memory system is powered down.

That is, in some examples, the second voltage offset group of the first memory block is obtained during operation before the memory system 102 is powered down.

In some examples, the power failure time of the memory system 102 is determined based on the first voltage offset group and the second voltage offset group, so that the power failure time is added to the retention time of the memory block in the memory device 104, and the retention time of the memory block in the memory device 104 is updated. In some examples, the fitting relationship between the voltage offset group and the retention time is constructed, so that the power failure time of the memory system 102 is determined by the retention times determined by the first voltage offset group and the second voltage offset group of the first memory block, respectively, then the retention time corresponding to the at least one memory block in the memory device 104 is updated, the retention time determination accuracy is improved, and the prediction accuracy of the retention time of the memory block in the memory device 104 is improved.

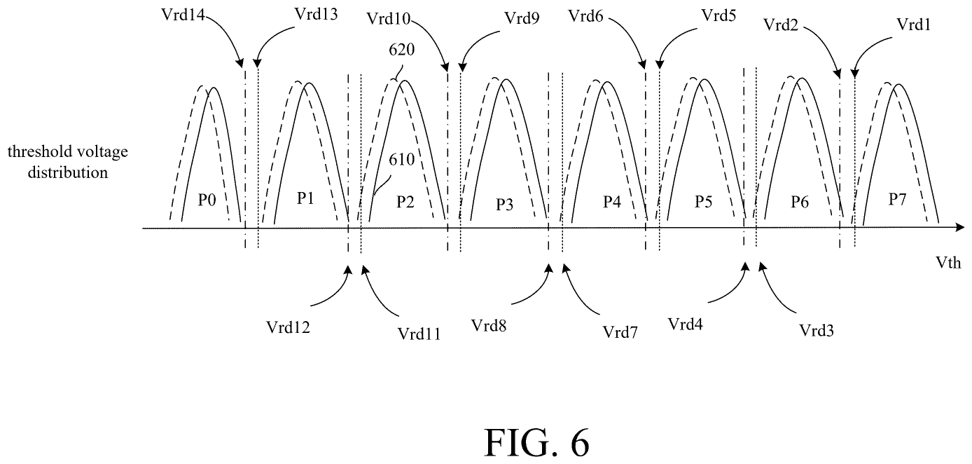

In some examples, the second voltage offset group is an offset group that is obtained by the memory system 102 and that is configured to express a plurality of threshold voltage distribution offsets in the first memory block during operation, that is, obtaining a plurality of differentiated voltages of a plurality of threshold voltage distributions in the first memory block, and if there is a certain time interval between the current moment and the moment at which the programming of the first memory block is completed, the plurality of differentiated voltages currently obtained are offset relative to the plurality of differentiated voltages when the programming of the first memory block is completed, and the second voltage offset group is used to express the offset. FIG. 6 is a schematic diagram of a TLC program threshold voltage distribution according to an example of the present disclosure, wherein when the programming of the memory cell in the first memory block is completed, the threshold voltage distribution of each state is shown in the solid curve 610 in FIG. 6. Taking the program state P7 as an example, the differentiated voltage between the program state P6 and the program state P7 is Vrd1, and after a period of time, the program state P6 and the program state P7 are offset, and the differentiated voltage between the program state P6 and the program state P7 is Vrd2. Taking the program state P6 as an example, the differentiated voltage between the program state P5 and the program state P6 is Vrd3, and after a period of time, the program state P5 and the program state P6 are offset, and the differentiated voltage between the program state P5 and the program state P6 is Vrd4. Taking the program state P5 as an example, the differentiated voltage between the program state P4 and the program state P5 is Vrd5, and after a period of time, the program state P4 and the program state P5 are offset, and the differentiated voltage between the program state P4 and the program state P5 is Vrd6. Taking the program state P4 as an example, the differentiated voltage between the program state P3 and the program state P4 is Vrd7, and after a period of time, the program state P3 and the program state P4 are offset, and the differentiated voltage between the program state P3 and the program state P4 is Vrd8. Taking the program state P3 as an example, the differentiated voltage between the program state P2 and the program state P3 is Vrd9, and after a period of time, the program state P2 and the program state P3 are offset, and the differentiated voltage between the program state P2 and the program state P3 is Vrd10. Taking the program state P2 as an example, the differentiated voltage between the program state P1 and the program state P2 is Vrd11, and after a period of time, the program state P1 and the program state P2 are offset, and the differentiated voltage between the program state P1 and the program state P2 is Vrd12. Taking the program state P1 as an example, the differentiated voltage between the erase state P0 and the program state P1 is Vrd13, and after a period of time, the erase state P0 and the program state P1 are offset, and the differentiated voltage between the erase state P0 and the program state P1 is Vrd14.

After obtaining the second voltage offset group, a power failure event occurs in the memory system 102, and the first voltage offset group is an offset group obtained for the first memory block and is configured to express a plurality of threshold voltage distribution offsets in the first memory block when the memory system 102 is powered on after powered down. That is, the second voltage offset group is a voltage offset group obtained before the memory system 102 is powered down, the first voltage offset group is a voltage offset group obtained when the memory system 102 is powered on after powered down, with at least a power failure time of the memory system 102 therebetween.

The power failure event may be implemented as an event initiated actively by the user to terminate supplying power to the memory system 102, or may be implemented as an event that the host 108 or the memory system 102 stops supplying power due to running errors. That is, the power failure event refers to an event that the memory system 102 ends working due to a power supply interruption. In the memory system 102, the method for detecting a power failure event comprises at least one of the following methods: (1) the memory controller 106 monitors the power supply voltage in real time, and when it is detected that the power supply voltage suddenly drops or falls below a threshold, determines that a power failure event occurs. (2) When the memory controller 106 receives the interrupt signal, it is determined that a power failure event occurs, wherein the interrupt signal may be sent by a power management chip inside the memory system 102, or may be sent by another external device connected to the memory system 102.

The memory system 102 according to some examples of the present disclosure determines the power failure time of the memory system 102 by obtaining the first voltage offset group and the second voltage offset group, so as to adjust the retention time corresponding to the at least one memory block in the memory device 104 based on the power failure time. In some examples, the at least one memory block refers to a memory block in which data is written in the memory device 104, and after the data is written in the memory block, the memory system 102 stores and updates a retention time corresponding to the memory block. In some examples, the at least one memory block refers to a memory block in which valid data is written in the memory device 104. The valid data refers to data that has an actual meaning to a user or an application program and can be normally used. In some examples, the valid data refers to data that is processed by an application program, conforms to service logic, and can be queried, modified, or applied for another operation. Correspondingly, invalid data refers to data generated due to a wrong write operation, data corruption or temporary placeholder.

In some examples, the retention time of the memory block is stored in a specified location in the memory system 102, for example, in a specified memory block; or, the memory block is correspondingly configured with a time counter, and the retention time of the memory block is saved and updated by the time counter.

The first memory block is a memory block in which data is written in the memory device 104. In some examples, the first memory block is randomly determined from the memory blocks in which the data is written in the memory device 104. Alternatively, the first memory block is a memory block that meets the first preset requirement in the memory device 104.

In some examples, when the memory device 104 comprises a plurality of memory blocks meeting the first preset requirement, the first memory block is randomly determined from the plurality of memory blocks meeting the first preset requirement; or, the first one of the memory blocks that is determined as meeting the first preset requirement is used as the first memory block; or, a memory block having a minimum program completion time in the plurality of memory blocks meeting the first preset requirement is selected as the first memory block; or, a memory block having a minimum retention time in the plurality of memory blocks meeting the first preset requirement is selected as the first memory block. The foregoing manner in which the first memory block is determined is merely an example, which is not limited in some examples of the present disclosure.

The first preset requirement comprises: 1.1, a retention time of the first memory block being less than a first preset duration; 1.2, a program temperature being within a preset temperature range; and 1.3, a duration in which programming of the first memory block has been completed reaching a second preset duration.

By setting the first preset requirement to constrain the selection process of the first memory block, a problem is avoided that the prediction accuracy of the retention time is not high due to the additional impacts that a high temperature, a low temperature, a too-long retention time, an insufficient programming completion duration have on the retention time prediction, and thus improving the accuracy of prediction of the power failure time.

1.1, The retention time of the first memory block being less than the first preset duration refers to that the retention time of data in the memory cell of the first memory block after the data is written in the first memory block is less than the first preset duration. For example, if the first preset duration is 3 days, the retention time of the first memory block is less than 3 days.

1.2, The program temperature of the first memory block being within the preset temperature range refers to that the operating temperature of the memory system 102 is within the preset temperature range when the memory cell in the first memory block is programmed. In some examples, in a process in which the memory cell in the first memory block is programmed, the operating temperature of the memory system 102 is collected by using the temperature sensor. In some examples, the program temperature at which the first memory block is programmed is expressed by the operating temperature collected by the temperature sensor.

Taking the temperature abnormal tag as an example, the preset temperature range is 68° to 140° Fahrenheit (F) (20° to 60° Celsius (C)), wherein the preset temperature range comprises or does not comprise 68° F. (20° C.), and the preset temperature range comprises or does not comprise 140° F. (60° C.). In the process of programming the memory cell in the memory block, the temperature data is collected by the temperature sensor, and when the temperature data exceeds the preset temperature range, the temperature abnormal tag is stored to the specified memory location corresponding to the memory block. In the process of obtaining the first memory block, when the specified memory location corresponding to the memory block does not comprise the temperature abnormal tag, it is determined that the program temperature of the memory block is within the preset temperature range.

Taking the temperature normal tag as an example, the preset temperature range is 68° to 140° F. (20° to 60° C.), wherein the preset temperature range comprises or does not comprise 68° F. (20° C.), and the preset temperature range comprises or does not comprise 140° F. (60° C.). In the process of programming the memory cell in the memory block, the temperature data is collected by the temperature sensor, and when the temperature data exceeds the preset temperature range in the programming process, the temperature normal tag is stored to the specified memory location corresponding to the memory block. In the process of obtaining the first memory block, when the specified memory location corresponding to the memory block comprises the temperature normal tag, it is determined that the program temperature of the memory block is within the preset temperature range.

In some examples, when the memory cell in the first memory block is programmed, the operating temperature value of the memory system 102 in the programming process of the memory cell in the first memory block is collected by the temperature sensor, and the temperature value is stored to the specified memory location. In some examples, the maximum value and the minimum value of the temperature value collected in the programming process are stored to the specified memory location, or the average value of the temperature values collected in the programming process is stored to the specified memory location. Subsequently, whether the program temperature of the first memory block is within the preset temperature range is determined according to the temperature value in the specified memory position.

In some examples, the first voltage offset group and the second voltage offset group are voltage offset groups obtained by reading the first memory block when the temperature is within a preset temperature range. By constraining the program temperature of the first memory block, the problem, that the read result of the voltage offset group is inaccurate due to cross-temperature reading and writing of the first memory block, is avoided.

1.3, the duration in which programming of the first memory block has been completed reaching a second preset duration, wherein the duration in which programming of the first memory block has been completed refers to the duration in which the programming of the memory cell in the first memory block has been completed and the memory block is ready to perform other operations. For example, the programming of the first memory block being completed refers to that the first memory block transitions from the open state to the closed state, indicating that the first memory block has completed the program operation, and no longer accepts new data writing. In this case, the state of the memory block may comprise: 1, data integrity: the data in the first memory block has been correctly programmed and checked, 2, the state label: the first memory block is labeled as “closed”, indicating that its programming process has completed, 3, availability: the first memory block may be used by other operations (such as reading or erasing).

For example, if the second preset duration is 10 minutes, if the duration in which the first memory block is in the closed state reaches 10 minutes, it indicates that the duration in which programming of the first memory block has been completed reaches the second preset duration.

In some examples, a duration in which the first memory block is in the closed state refers to a duration between a start moment at which the first memory block most recently switches to the closed state and a current moment, that is, a duration in which the first memory block is continuously in the closed state. For example, if the first memory block is in the closed state at the first moment in the historical time period, switches from the closed state to the open state at the second moment, and switches from the open state to the closed state again at the third moment, the duration in which the first memory block is in the closed state refers to the duration between the third moment and the current moment.

When the first memory block is determined based on the first preset requirement, it comprises at least one of the following cases:
First, if the memory block stores the memory block information related to the first preset requirement, the memory block in the memory device 104 is scanned to obtain the memory block information of each memory block, and the first memory block is determined from the scanning result;
Second, if the memory controller 106 stores the memory block information related to each memory block and the first preset requirement, for example, if the buffer of the memory controller 106 buffers the memory block information related to each memory block and the first preset requirement, the first memory block is determined based on the memory block information buffered in the buffer;
Third, if the specified memory block in the memory device 104 stores the memory block information related to each memory block and the first preset requirement, a read operation is performed on the specified memory block, and the first memory block is determined according to the read memory block information.

It should be noted that the foregoing manner in which the first memory block is determined is merely an example, which is not limited in some examples of the present disclosure.

In some examples, the memory controller 106 is further configured to: in response to the first memory block failing to match the first preset requirement, determine a second memory block meeting a second preset requirement; obtain a third voltage offset group of the second memory block in response to the memory system 102 being powered on after powered down; and adjust the retention time corresponding to the at least one memory block in the memory device based on the third voltage offset group and a fourth voltage offset group, wherein the fourth voltage offset group is a voltage offset group of the second memory block obtained before the memory system 102 is powered down.

For example, during operation of the memory system 102, in response to the first memory block failing to match the first preset requirement, the second memory block meeting the second preset requirement is determined; a fourth voltage offset group of the second memory block is obtained; in response to the memory system 102 being powered down, a the third voltage offset group of the second memory block is obtained, and the retention time corresponding to the at least one memory block in the memory device 104 is adjusted based on the third voltage offset group and the fourth voltage offset group.

The second preset requirement comprises: 2.1, a retention time of the second memory block being less than the third preset duration, and the retention time of the second memory block being less than or equal to a retention time of another memory block whose programming has been completed in the memory device 104; 2.2, the program temperature of the second memory block being within the preset temperature range; and 2.3, a duration in which programming of the second memory block has been completed reaching a fourth preset duration.

By setting the second preset requirement to constrain the selection process of the second memory block, the problem, that the prediction accuracy of the retention time is not high due to the additional impacts that a high temperature, a low temperature, a too-long retention time, an insufficient programming completion duration have on the retention time prediction, is avoided, thus improving the accuracy of prediction of the power failure time.

2.1, a retention time of the second memory block being less than the third preset duration, and the retention time of the second memory block being less than or equal to a retention time of another memory block whose programming has been completed in the memory device 104 refers to that the retention time of data in the memory cell of the second memory block after the data is written in the second memory block is less than the third preset duration, and the retention time of the second memory block is the smallest among the memory blocks whose programming has been completed in the memory device 104, wherein the memory blocks whose programming has been completed refers to the memory blocks in the closed state. The third preset duration is the same as or different from the first preset duration, and taking the third preset duration being the same as the first preset duration as an example, for example, the first preset duration and the third preset duration are 3 days, and the retention time of the second memory block is less than 3 days.

2.2, The program temperature of the second memory block being within the preset temperature range refers to that the operating temperature of the memory system 102 is within the preset temperature range when the memory cell in the second memory block is programmed. In some examples, in a process in which the memory cell in the second memory block is programmed, the operating temperature of the memory system 102 is collected by using the temperature sensor. In some examples, the program temperature at which the second memory block is programmed is expressed by the operating temperature collected by the temperature sensor.

In some examples, when the memory cell in the second memory block is within the preset temperature range during programming, the temperature normal tag is stored in the specified location corresponding to the second memory block, or when the memory cell in the second memory block is not within the preset temperature range during programming, the temperature abnormal tag is stored in the specified location corresponding to the second memory block. A second memory block having a program temperature within a preset temperature range is determined from the memory device 104 based on the temperature normal tag or the temperature abnormal tag.

Taking the temperature abnormal tag as an example, the preset temperature range is 68° to 140° F. (20° to 60° C.), wherein the preset temperature range comprises or does not comprise 68° F. (20° C.), and the preset temperature range comprises or does not comprise 140° F. (60° C.). In the process of programming the memory cell in the memory block, the temperature data is collected by the temperature sensor, and when the temperature data exceeds the preset temperature range, the temperature abnormal tag is stored to the specified location corresponding to the memory block. In the process of obtaining the second memory block, when the specified location corresponding to the memory block does not comprise the temperature abnormal tag, it is determined that the program temperature of the memory block is within the preset temperature range.

In some examples, when the memory cell in the second memory block is programmed, the operating temperature value of the memory system 102 in the programming process of the memory cell in the second memory block is collected by the temperature sensor, and the temperature value is stored to the specified memory location corresponding to the second memory block. In some examples, the maximum value and the minimum value of the temperature value collected in the programming process are stored to the specified memory location corresponding to the second memory block, or the average value of the temperature values collected in the programming process is stored to the specified memory location corresponding to the second memory block. Subsequently, it is determined that whether the program temperature of the second memory block is within the preset temperature range according to the temperature value in the specified memory position.

2.3, the duration in which programming of the second memory block has been completed reaching a fourth preset duration, wherein the duration in which programming of the second memory block has been completed refers to the duration in which the programming of the memory cell in the second memory block has been completed and the memory block is ready to perform other operations. For example, the programming of the second memory block being completed refers to that the second memory block transitions from the open state to the closed state, indicating that the second memory block has completed the program operation, and no longer accepts new data writing.

The fourth preset duration is the same as or different from the second preset duration. For example, taking the fourth preset duration being the same as the second preset duration as an example, wherein the second preset duration and the fourth preset duration are 10 minutes, if the duration in which the second memory block is in the closed state reaches 10 minutes, it indicates that the duration in which programming of the second memory block has been completed reaches the second preset duration.

When the second memory block is determined based on the second preset requirement, it comprises at least one of the following cases:
First, if the memory block stores the memory block information related to the second preset requirement, the memory block in the memory device 104 is scanned to obtain the memory block information of each memory block, and the second memory block is determined from the scanning result;
Second, if the memory controller 106 stores the memory block information related to each memory block and the second preset requirement, for example, if the buffer of the memory controller 106 buffers the memory block information related to each memory block and the second preset requirement, the second memory block is determined based on the memory block information buffered in the buffer;
Third, if the specified memory block in the memory device 104 stores the memory block information related to each memory block and the second preset requirement, a read operation is performed on the specified memory block, and the second memory block is determined according to the read memory block information.

It should be noted that the foregoing manner in which the second memory block is determined is merely an example, which is not limited in some examples of the present disclosure.

The second memory block is a memory block determined when the first memory block fails to match the first preset requirement. In some examples, the memory controller 106 obtains the memory block information of the first memory block according to a preset first period, and determines whether the memory block information of the first memory block matches the first preset requirement, for example, the memory controller 106 obtains the memory block information of the first memory block every 10 seconds, and determines whether the memory block information of the first memory block matches the first preset requirement, and the memory controller 106 is further configured to: when the memory block information of the first memory block fails to match the first preset requirement, determine the second memory block. For example, when the retention duration of the first memory block exceeds the first preset duration, the second memory block is determined.

If the memory block information of the first memory block matches the first preset requirement, the second voltage offset group of the first memory block is continued to be obtained and updated.

In some examples, the memory controller 106 is further configured to: in response to absence of a memory block that meets the second preset requirement in the memory device 104, use the first memory block as a memory block for which the retention time is adjusted. That is, when the first memory block fails to match the first preset requirement, the memory controller 106 searches the second memory block according to the second preset requirement, and if there is no second memory block that meets the second preset requirement in the memory device 104, continues to use the first memory block as a memory block for which the retention time is adjusted, that is, continues to obtain the second voltage offset group of the first memory block.

In some examples, during operation of the memory system, the memory controller 106 periodically obtains a second voltage offset group of the first memory block. For example, the memory controller 106 obtains the second voltage offset group of the first memory block according to a preset second period, wherein the second period is the same as the first period, or the second period is different from the first period.

By periodically obtaining the second voltage offset group, the problem that the second voltage offset group cannot be obtained in time due to abnormal power failure is avoided, and the second voltage offset group is periodically obtained and stored, and the obtained second voltage offset group is stored in the buffer, so that when the memory system 102 is powered down, the second voltage offset group recently written can be directly obtained from the buffer and written into the memory device 104, in order to be accessed by the memory system 102 in time after being powered on, and the reliability of predicting the power failure time is improved. When the first period and the second period are the same preset period, in some examples, the memory controller 106 obtains the memory block information of the first memory block according to the preset period, and determines whether the memory block information of the first memory block matches the first preset requirement, and when the memory block information of the first memory block matches the first preset requirement, obtains the second voltage offset group of the first memory block.

When the first period and the second period are different preset periods, in some examples, the memory controller 106 obtains the memory block information of the first memory block according to the first period, and determines whether the memory block information of the first memory block matches the first preset requirement, and when the memory block information of the first memory block matches the first preset requirement, collects the second voltage offset group of the first memory block at a most recent time reaching the second period after the current moment, and when the memory block information of the first memory block fails to match the first preset requirement, determines the second memory block, and collects the fourth voltage offset group of the second memory block at a most recent time reaching the second period after the current moment.

In some examples, when the first memory block is used as the memory block for which the retention time is adjusted, the memory block identifier of the first memory block is saved, for example, a logical address or other identifier information. Similarly, when the second memory block is used as the memory block for which the retention time is adjusted, the memory block identifier of the second memory block is saved. The memory block identifier is stored in a buffer of the memory controller 106, and is saved to the memory device 104 when the memory system 102 is powered down, or the memory block identifier is stored in a specified address in the memory device 104.

The above voltage offset group is described. The second voltage offset group is a voltage offset group collected for the first memory block during operation of the memory system 102, the first voltage offset group is a voltage offset group collected for the first memory block after the memory system 102 is powered down and re-powered on, the fourth voltage offset group is a voltage offset group collected for the second memory block after the second memory block is determined based on the second preset requirement when the first memory block fails to match the first preset requirement during operation of the memory system 102, and the third voltage offset group is a voltage offset group collected for the second memory block after the memory system 102 is powered down and re-powered on.

The first voltage offset group and the second voltage offset group are taken as an example for description.

The second voltage offset group: in some examples, the memory controller 106 is further configured to: obtain the second voltage offset group of the first memory block periodically during operation of the memory system 102; write a latest obtained second voltage offset group to the memory device 104 in response to the memory system 102 being powered down; and read the second voltage offset group from the memory device 104 in response to the memory system 102 being powered on after powered down.

When the second voltage offset group of the first memory block is obtained, in some examples, the default threshold voltage group is used first, and the error correction is performed on the error bits of the first memory block by using an error correction code (ECC) error correction engine.

Taking the ECC error correction as an example, before the user data is written into the first memory block, the user data is firstly ECC encoded to generate verification data, and the verification data and the user data are written into the flash memory. When the user data is verified, the user data and the verification data are undergone the ECC error correction to determine the number of bits that are flipped in the user data.

Taking Low-Density Parity-Check (LDPC) error correction as an example, when reading user data, the user data comprises original information bits and redundant check bits, and each information bit and each check bit corresponds to one variable node. During initialization, the variable node stores the received bit value, and each check equation corresponds to one check node. During initialization, the check node records the initial message of the variable node to which it is connected, which is usually set to zero or null. Message passing is a core step of LDPC decoding, and information is exchanged between the variable node and the check node in an iterative manner, and the confidence of correctness of each bit is gradually updated. For each variable node, messages from all connected check nodes (except the check node currently being processed) are received and combined with its own received value to calculate a message sent to each check node. For each check node, messages from all connected variable nodes (except the variable node currently being processed) are received, and a message sent to each variable node is calculated according to the parity check constraint. After several message passing iterations are completed, the decoder needs to perform hard decisions on each variable node, that is, determine the final estimated value of each bit.

The voltage offset group corresponding to the threshold voltage group is adjusted according to the number of error bits of the read result, and the first memory block is read by the adjusted voltage offset group to obtain the read result, the voltage offset group is updated repeatedly for multiple times until the ECC decoding succeeds. That is, a group of differentiated voltages that distinguish the plurality of threshold voltage distributions are obtained by adjusting the voltage offset group, and a voltage offset group corresponding to the group of differentiated voltages is obtained.

In some examples, during operation of the memory system 102, a read operation is performed on the first memory block by using at least two candidate voltage offset groups to obtain read results of the at least two candidate voltage offset groups, and a second voltage offset group is determined based on the read results and the at least two candidate voltage offset groups.

In some examples, the voltage offset group when the ECC is successfully decoded is used as the second voltage offset group.

For example, taking the memory cell in the first memory block comprising TLC as an example, each memory cell can store 3 bits of data, that is, the memory cell can be programmed to an erase state and seven program states corresponding to the bit codes 111, 110, 100, 000, 010, 011, 001, and 101. For example, FIG. 6 is a schematic diagram of a TLC programming threshold voltage distribution according to an example of the present disclosure, when programming of a memory cell in a first memory block is completed, a threshold voltage distribution of each state is shown in a solid curve 610 in FIG. 6. The storage layer of the memory cell is surrounded by the insulator, and electrons stored in the storage layer of the memory cell can be lost under the effect of the intrinsic electric field over time, and especially as the insulation effect of the tunnel oxide layer deteriorates with the increase of the number of erasing times, the phenomenon of electron loss is more apparent. When the amount of the electron loss reaches a certain extent, the bit in the memory cell is flipped, that is, as the retention time increases, the electrons in the memory cell are lost, resulting in the threshold voltage offset. Taking the threshold voltage offset to the left as an example, as shown by the dashed curve 620 in FIG. 6.

In some examples, the voltage offsets corresponding to different program states are the same or different, wherein taking the TLC shown in FIG. 6 as an example, the second voltage offset group comprises at least one of the following: a voltage offset of a differentiated voltage for distinguishing between the erase state P0 and the program state P1, a voltage offset of a differentiated voltage for distinguishing between the program state P1 and the program state P2, a voltage offset of a differentiated voltage for distinguishing between the program state P2 and the program state P3, a voltage offset of a differentiated voltage for distinguishing between the program state P3 and the program state P4, a voltage offset of a differentiated voltage for distinguishing between the program state P4 and the program state P5, a voltage offset of a differentiated voltage for distinguishing between the program state P5 and the program state P6, and a voltage offset of a differentiated voltage for distinguishing between the program state P6 and the program state P7.

In some examples, the second retention time corresponding to the second voltage offset group is obtained. The obtaining the second retention time comprises at least one of the following manners:

First, a second voltage offset corresponding to the first program state is obtained from the second voltage offset group, and a second retention time corresponding to the second voltage offset is obtained.

The second voltage offset is obtained for the first program state, so that the offsets of the threshold voltage distributions between the program states in the first memory block is reflected more intuitively, and the acquisition efficiency of the second retention time is improved.

For example, taking the first memory block comprising TLC as an example, the second voltage offset corresponding to the program state P7 is obtained from the second voltage offset group, that is, the second voltage offset of a differentiated voltage for distinguishing between the program state P6 and the program state P7, and the second retention time corresponding to the second voltage offset is obtained. The first program state is any program state, or the first program state is a predefined program state.

Second, an average value of at least two voltage offsets in the second voltage offset group is obtained as the second voltage offset, and a second retention time corresponding to the second voltage offset is obtained.

The at least two voltage offsets may be implemented as all voltage offsets in the first voltage offset group, or may be implemented as a portion of voltage offsets.

The average value of the at least two voltage offsets is obtained as the second voltage offset for the at least two program states, so that the offsets of the threshold voltage distributions between the program states in the first memory block is reflected more accurately, and the acquisition accuracy of the second retention time is improved.

For example, taking the first memory block comprising TLC as an example, the average value of the voltage offsets corresponding to the program state P5, the program state P6 and the program state P7 is obtained from the second voltage offset group as the second voltage offset, that is, the voltage offset between the program state P4 and the program state P5 is obtained, the voltage offset between the program state P5 and the program state P6 is obtained, the voltage offset between the program state P6 and the program state P7 is obtained, and the average value of the above voltage offsets is calculated as the second voltage offset.

It should be noted that the foregoing manner of determining the second voltage offset is merely an example, and this is not limited in some examples of the present disclosure.

In some examples, during operation of the memory system 102, the memory controller 106 is further configured to: obtain the second voltage offset of the first memory block periodically, write the second voltage offset into the buffer, and write the second voltage offset written in the buffer last time into the memory device 104 in response to receiving the power-down signal of the memory system 102. Alternatively, during operation of the memory system 102, obtain the second voltage offset group of the first memory block periodically, write the second voltage offset group into the buffer, and write the second voltage offset group written in the buffer last time into the memory device 104 in response to receiving the power-down signal of the memory system 102, and after the memory system 102 is powered on, read the second voltage offset group from the memory device 104 and obtain the second voltage offset.

Taking the SSD as an example, a backup capacitor may be welded on a printed circuit board (PCB) of the SSD, after a power failure event occurs in the SSD, the backup capacitor provides power to the SSD, and a second voltage offset written in the buffer last time is written into the memory device 104.

In some examples, the power failure event is only a schematic example, and in response to the memory system 102 generating the preset trigger event, the second voltage offset is written into the memory device 104, for example, the operating temperature of the memory system 102 generates an abnormal event, for example, exceeding a preset temperature range. The timing of writing the second voltage offset into the memory device 104 is not limited in some examples of the present disclosure.

The first voltage offset group: in response to the memory system 102 being powered on after powered down, a first voltage offset group corresponding to the first memory block is obtained. In some examples, the memory block corresponding to the second voltage offset group obtained when the memory system is powered down is first determined, that is, the first memory block, and then the second voltage offset group corresponding to the first memory block is obtained. In some examples, when the second voltage offset group is stored, the memory block identifier of the memory block corresponding to the second voltage offset group is correspondingly stored, and the memory block identifier comprises at least one of identifiers such as a memory block address, a memory block number, and the like.

In some examples, the first voltage offset group is obtained in a preset phase in which the memory system 102 is powered on. For example, the power-on process of the memory system 102 comprises at least one of the following phases: 1, a power supply is turned on, wherein the memory system 102 is connected to a power supply, and the power management unit is activated to supply power to each module of the memory system 102; 2, a hardware self-check, wherein self-check is performed on each hardware module and interface in the memory system 102; 3, initialization of the controller, such as firmware loading, basic function initialization, etc.; 4, initialization of the storage medium, for example, detecting whether the storage medium is correctly connected, obtaining attribute data of the storage medium, and the like, 5, initialization of the file system and the logical structure; 6, interaction between the driver and the operating system, for example, identifying and loading a driver for driving the memory system 102 through the operating system of the host 108; 7, data integrity verification and recovery for performing data check and recovery; and 8, system ready.

In some examples, the second voltage offset stored when the system is powered down is obtained in the data integrity verification and recovery phase, and the first voltage offset group is obtained for the first memory block.

In some examples, the obtaining manner of the first voltage offset group refers to the obtaining manner of the second voltage offset group, and details are not described herein again.

In some examples, the first retention time corresponding to the first voltage offset group is obtained. The obtaining the first retention time comprises at least one of the following manners:

First, a first voltage offset corresponding to the first program state is obtained from the first voltage offset group, and a first retention time corresponding to the first voltage offset is obtained.

For example, taking the first memory block comprising TLC as an example, the first voltage offset corresponding to the program state P7 is obtained from the first voltage offset group, that is, the first voltage offset for distinguishing the program state P6 and the program state P7, and the first retention time corresponding to the first voltage offset is obtained. The first program state is any program state, or the first program state is a predefined program state.

Second, an average value of at least two voltage offsets in the first voltage offset group is obtained as a first voltage offset, and a first retention time corresponding to the first voltage offset is obtained.

For example, taking the first memory block comprising TLC as an example, the average value of the voltage offsets corresponding to the program state P5, the program state P6 and the program state P7 is obtained from the first voltage offset group as the first voltage offset, that is, the voltage offset between the program state P4 and the program state P5 is obtained, the voltage offset between the program state P5 and the program state P6 is obtained, the voltage offset between the program state P6 and the program state P7 is obtained, and the average value of the above voltage offsets is calculated as the first voltage offset.

It should be noted that the foregoing manner of determining the first voltage offset is merely an example, and this is not limited in some examples of the present disclosure, and the first voltage offset and the second voltage offset are obtained according to a same rule.

In some examples, the power failure time of the memory system is obtained based on the first retention time and the second retention time, and the retention time corresponding to the at least one memory block is adjusted by the power failure time. The first retention time is a retention time collected for the first memory block after the system is powered down, a time difference between the first retention time and the second retention time is obtained as the power failure time, and the retention time corresponding to the at least one memory block is adjusted by the power failure time, for example, adding the power failure time to the retention time of the at least one memory block to obtain the updated retention time of the at least one memory block.

In some examples, when the first retention time is determined based on the first voltage offset, the first retention time is calculated by the preset fitting formula and the first voltage offset.

In some examples, since the data retention capability is related to the number of times of erasing of the flash memory, the greater the number of times of erasing, the worse the data retention capability and the shorter the data retention period. Therefore, the first retention time is determined based on the number times of historical erasing and the first voltage offset of the first memory block, and the second retention time is determined based on the number of historical erasing times and the second voltage offset.

For example, the fitting formula between the voltage offset and the retention time is as follows:

PE 0-1K: y=a₁x²−b₁x+c₁ (1)

PE 1-3K: y=a₂x²−b₂x+c₂; (2)

PE 3-7K: y=a₃x²−b₃x+c₃; (3)

PE≥7K: y=a₄x²−b₄x+c₄. (4)

Wherein a₁, b₁, c₁, a₂, b₂, c₂, a₃, b₃, c₃, a₄, b₄, c₄ is a preset known parameter, and the four fitting formulas are different.

For example, a₁ value is 1.53, b₁ value is 12.73, and c₁ value is 28.09.

Wherein PE 0-1K refers to that the number of historical erasing times (e.g., previous erase (PE) times) is in a range of 0 to 1000, including 0 and excluding 1000; PE 1-3K refers to that the number of historical erasing times is in a range of 1000 to 3000, including 1000 and excluding 3000; PE 3-7K refers to that the number of historical erasing times is in a range of 3000 to 7000, including 3000 and excluding 7000; and PE≥7K refers to that the number of historical erasing times is in a range of greater than or equal to 7000.

In some examples, the number of historical erasing times of the first memory block is stored in a specified memory location corresponding to the first memory block, the number of historical erasing times of the first memory block is obtained from the specified memory location corresponding to the first memory block, and the first retention time corresponding to the first voltage offset of the first memory block is calculated based on the fitting formula corresponding to the number of historical erasing times.

It should be noted that the range of the number of historical erasing times corresponding to the fitting formula above is merely illustrative, and the range of the number of historical erasing times corresponding to the fitting formula may be divided by other dividing granularities, for example, 0-1K, 1-2K, 2-3K, and so on, and the manner of dividing the range of the number of historical erasing times is not limited in some examples of the present disclosure. In addition, a formula form of the fitting formula is merely an example, and the fitting formula may also be implemented as a third-order formula, a prescribing formula, or any other form of formula, and a formula form of the fitting formula is not limited in some examples of the present disclosure.

When predicting the retention time, consider the number of historical erasing times of the first memory block to avoid the problem of poor accuracy in predicting the retention time of the first memory block due to too few or too many times of historical erasing of the first memory block. By dividing the range of the number of times of erasing, based on the range corresponding to the number of historical erasing times of the first memory block, the retention times of the first memory block before the power failure and after the power failure are predicted by using the fitting formula corresponding to the range, thus the power failure time of the memory system 102 is predicted, the prediction accuracy of the power failure time is improved, and the influence of the number of historical erasing times on predicting the power failure time is reduced.

The corresponding fitting formula is used for calculation according to the number of historical erasing times of the first memory blocks. For example, if the number of historical erasing times of the first memory block is 3200, the retention time corresponding to the first voltage offset and the second voltage offset is calculated using the formula (3). x corresponds to the voltage offset, and y is the calculated retention time. The first voltage offset is substituted as the value of x into the formula (3) to obtain the first retention time rttTime1, and the second voltage offset is substituted as the value of x into the formula (3) to obtain the second retention time rttTime2, and the power failure time is calculated and obtained as tPowerOff=rttTime1−rttTime2.

The power failure time tPowerOff is added to the retention time of each memory block to which data has been written in the memory device 104, to obtain the updated retention time corresponding to each memory block.

It should be noted that, in the foregoing example, taking an example in which the first voltage offset group and the second voltage offset group are obtained based on the first memory block for description, and in some examples, when the third voltage offset group and the fourth voltage offset group are obtained based on the second memory block, the obtaining manner may refer to the foregoing process of obtaining the first voltage offset group and the second voltage offset group, and details are not described herein again.

In some examples, after obtaining the second memory block when the first memory block fails to match the first preset requirement, the second memory block is considered as an updated first memory block, and the same determination logic and data acquisition logic are performed on the second memory block as the first memory block.

In conclusion, in the memory system provided in some examples of the present disclosure, when the memory system is powered down and powered on again, the first voltage offset group of the first memory block is obtained, so that the power failure time of the memory system is predicted through the first voltage offset group and the second voltage offset group obtained before powered down, and the power failure time is added to the retention time of the memory block, the retention time of the memory block is adjusted, which improves the accuracy of recording the retention time of the memory block, thereby improving the timeliness and accuracy of the memory system when performing the reliability actions on the memory block based on the retention time, and improving the running stability of the memory system.

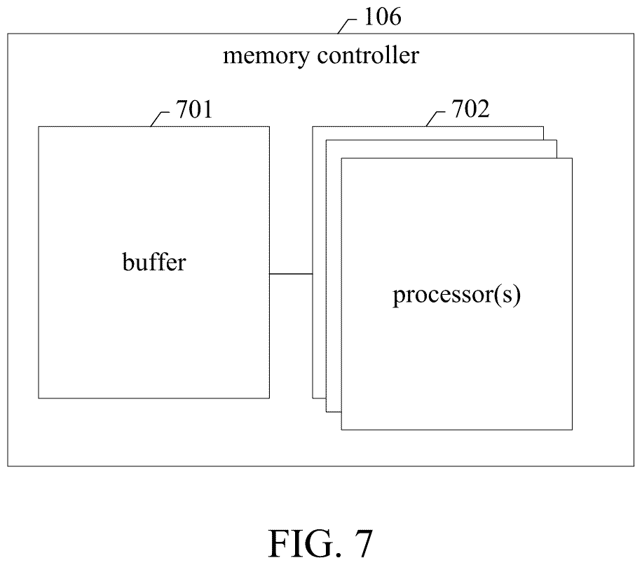

FIG. 7 is a schematic structural diagram of a memory controller 106 according to some examples of the present disclosure. As shown in FIG. 7, the memory controller 106 comprises a buffer 701 and one or more processors 702. The buffer 701 is configured to buffer a voltage offset or a voltage offset group, and in some examples of the present disclosure, taking the buffer 701 being configured to buffer voltage offset as an example for description. In some examples, the buffer 701 comprises a buffer and a cache in the memory controller 106, wherein both the buffer and the cache may be implemented as Dynamic Random Access Memory (DRAM) or Static Random Access Memory (SRAM). For example, the first voltage offset is buffered in the buffer, or the first voltage offset is buffered in the cache, which is not limited herein.

The one or more processors 702 are configured to: obtain a first voltage offset group of a first memory block in response to the memory system 102 being powered on after powered down; and adjust a retention time corresponding to at least one memory block in the memory device 104 based on the first voltage offset group and a second voltage offset group, wherein the second voltage offset group is a voltage offset group of the first memory block obtained before the memory system 102 is powered down.

In some examples, the first memory block meets a first preset requirement, the first preset requirement comprises:
a retention time of the first memory block being less than a first preset duration,
a program temperature being within a preset temperature range,
a duration in which programming of the first memory block has been completed reaching a second preset duration.

In some examples, the one or more processors 702 are further configured to:
in response to the first memory block failing to match the first preset requirement, determine a second memory block meeting a second preset requirement;
obtain a third voltage offset group of the second memory block in response to the memory system 102 being powered on after powered down; and
adjust the retention time corresponding to the at least one memory block in the memory device 104 based on the third voltage offset group and a fourth voltage offset group, wherein the fourth voltage offset group is a voltage offset group of the second memory block obtained before the memory system 102 is powered down.

In some examples, the second preset requirement comprises:
a retention time of the second memory block being less than a third preset duration, and the retention time of the second memory block being less than or equal to a retention time of another memory block whose programming has been completed in the memory device 104,
a program temperature being within the preset temperature range, and
a duration in which programming of the second memory block has been completed reaching a fourth preset duration.

In some examples, the one or more processors 702 are further configured to:
in response to there being no memory block that meets the second preset requirement in the memory device 104, use the first memory block as a memory block for which the retention time is adjusted.

In some examples, the one or more processors 702 are further configured to:
during operation of the memory system 102, obtain the second voltage offset group of the first memory block periodically, and write the obtained second voltage offset group into the buffer 701;
write a second voltage offset group written into the buffer 701 last time to the memory device 104 in response to the memory system 102 being powered down; and
read the second voltage offset group from the memory device 104 in response to the memory system 102 being powered on after powered down.

In some examples, the one or more processors 702 are further configured to:
during operation of the memory system 102, perform a read operation on the first memory block by at least two candidate voltage offset groups to obtain read results of the at least two candidate voltage offset groups; and
determine the second voltage offset group based on the read results and the at least two candidate voltage offset groups.

In some examples, the one or more processors 702 are further configured to:
obtain a first voltage offset corresponding to a first program state from the first voltage offset group; and
obtain a second voltage offset corresponding to the first program state from the second voltage offset group.

In some examples, the one or more processors 702 are further configured to:
obtain a first retention time corresponding to the first voltage offset;
obtain a second retention time corresponding to the second voltage offset;
obtain a power failure time of the memory system 102 based on the first retention time and the second retention time; and
adjust the retention time corresponding to the at least one memory block through the power failure time.

In some examples, the one or more processors 702 are further configured to:
determine the first retention time based on a number of historical erasing times of the first memory block and the first voltage offset; and
determine the second retention time based on the number of historical erasing times and the second voltage offset.

In some examples, the memory system 102 comprises a solid state drive SSD.

The following uses an example in which the memory system provided in the present disclosure is implemented as a solid state drive (SSD) for description.

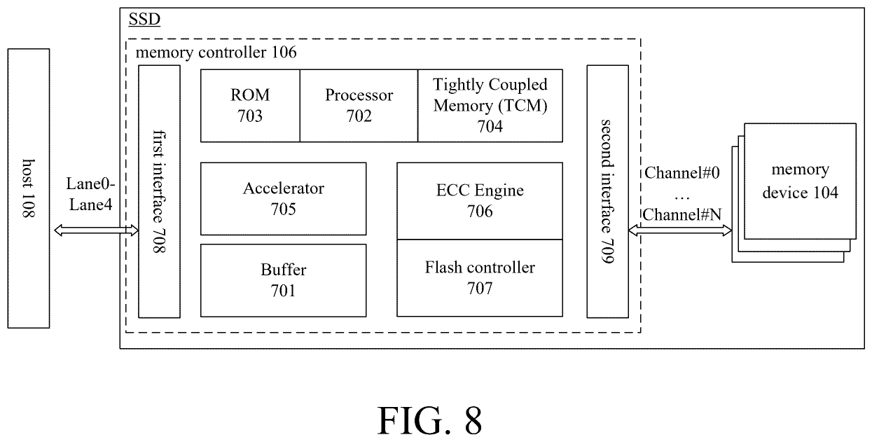

FIG. 8 is a schematic diagram of a computer system according to some examples of the present disclosure. As shown in FIG. 8, the computer system comprises a solid state drive SSD and a host 108.

The SSD comprises a memory device 104 and a memory controller 106. For example, the memory controller 106 may be implemented as a system on chip (SOC) chip in an SSD, or the memory controller 106 is integrated on an SOC chip in an SSD.

The memory device 104 is a part of an SSD for storing data, and is usually composed of a flash memory (such as a NAND flash memory). The memory device 104 is responsible for storing user data and system metadata.

The memory controller 106 is a core control unit in the SSD, and is responsible for managing read and write operations, address mapping, error detection and correction, and the like of data. Various components of the memory controller 106 are as follows:
buffer 701: temporarily stores data to improve data read and write speed. In the write operation, the user data is first written to the buffer 701 and then gradually written to the memory device 104. This may reduce frequent access to the memory device 104 and improve overall performance.
one or more processors 702: execute core control logic of the SSD, such as the control method of the memory system in the present disclosure.
read-only memory (ROM) 703: stores firmware and boot code, and these codes run when the SSD is powered on, initialize the memory controller 106, and start the memory system 102.
tightly coupled memory (TCM) 704: a high-speed memory for storing frequently accessed data and code. Tightly coupled memory may provide low latency access, improving performance of processor.
accelerator 705: accelerates specific operations, such as data encryption, decryption, and compression.
error correction code (ECC) engine 706: detects and corrects errors during data transmission. The error correction code engine 706 adds redundant information to the original data, and uses the additional information to identify and correct error codes that may occur at the receiving end, significantly improving the integrity and reliability of the data.
flash controller 707: responsible for directly managing operations of flash memory, such as NAND flash memory, comprising read and write operations, block management, wear leveling, and garbage collection. The flash controller 707 ensures efficient and reliable operation of the flash memory.

The first interface 708: connects the host 108 and the memory controller 106, ensuring that the host 108 can efficiently exchange data with the SSD. As shown in FIG. 8, “lane0-lane4” between the first interface 708 and the host represents a physical connection channel between the memory controller 106 and the host.

The second interface 709: connects the memory device 104 and the memory controller 106, to implement data transmission between the memory device 104 and the memory controller 106. As shown in FIG. 8, “Channel #0-Channel #N” between the second interface 709 and the memory device 104 represents an independent data channel for data exchange between the memory controller 106 and the memory device 104.

In the present disclosure, a target code is run in a tightly coupled memory (TCM) 704 or a cache (not shown in FIG. 8) in the memory controller 106, and the target code is configured to implement the control method of the memory system provided in the present disclosure. The target code is stored in the memory device 104.

Next, a specific flow of the control method of the memory system according to the present disclosure is described.

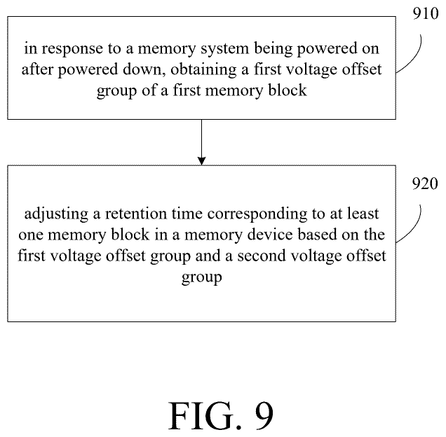

FIG. 9 is a flowchart of a control method of a memory system according to some examples of the present disclosure, the memory system 102 provided by the present disclosure comprises a memory device 104 and a memory controller 106. In some examples, the memory system 102 comprises a solid state drive SSD. In some examples, the memory device 104 comprises a trinary-level cell TLC.

The control method of the memory system is executed by the memory controller 106. The method comprises the following operations 910 to 930.

Operation 910: obtaining a first voltage offset group of a first memory block in response to the memory system being powered on after powered down.

In some examples, the second voltage offset group of the first memory block is obtained before the memory system 102 is powered down.

In some examples, the memory controller 106 comprises a buffer 701, and the buffer 701 is configured to buffer the voltage offset group or the voltage offset collected in this example.

In some examples, the second voltage offset group is an offset group for the first memory block that is obtained by the memory system 102 and that is used to express a plurality of threshold voltage distribution offsets in the first memory block during operation, that is, obtaining a plurality of differentiated voltages of a plurality of threshold voltage distributions in the first memory block, and if there is a certain time interval between the current moment and the moment at which the programming of the first memory block is completed, the plurality of differentiated voltages currently obtained are offset relative to the plurality of differentiated voltages when the programming of the first memory block is completed, and the first voltage offset group is used to express the offset.

The first memory block is a memory block into which data is written in the memory device 104. In some examples, the first memory block is randomly determined from the memory blocks into which the data is written in the memory device 104. Alternatively, the first memory block is a memory block that meets the first preset requirement in the memory device 104.

In some examples, when the memory device 104 comprises the plurality of memory blocks meeting the first preset requirement, the first memory block is randomly determined from the plurality of memory blocks meeting the first preset requirement, or the first one of the memory blocks that is determined as meeting the first preset requirement is used as the first memory block, or a memory block having a minimum program completion time in the plurality of memory blocks meeting the first preset requirement is selected as the first memory block, or a memory block having a minimum retention time in the plurality of memory blocks meeting the first preset requirement is selected as the first memory block. The foregoing manner in which the first memory block is determined is merely an example, which is not limited in some examples of the present disclosure.

The first preset requirement comprises: 1.1, a retention time of the first memory block being less than a first preset duration, 1.2, a program temperature of the first memory block being within a preset temperature range, and 1.3, a duration in which programming of the first memory block has been completed reaching a second preset duration.

For example, the first preset requirement comprises: \textcircled{1} retention time being less than 3 days, \textcircled{2} program temperature being between [68, 140]° F. ([20, 60]° C.), high temperature and low temperature are excluded, and a search valley effect caused by cross-temperature write and read is prevented, and \textcircled{3} close time being greater than 10 mins.

During operation of the memory system 102, in response to the first memory block failing to match the first preset requirement, a second memory block meeting a second preset requirement is determined; a third voltage offset group of the second memory block is obtained in response to the memory system 102 being powered on after powered down; and the retention time corresponding to the at least one memory block in the memory device 104 is adjusted based on the third voltage offset group and a fourth voltage offset group, wherein the fourth voltage offset group is a voltage offset group of the second memory block obtained before the memory system 102 is powered down.

The second preset requirement comprises: 2.1, a retention time of the second memory block being less than the third preset duration, and the retention time of the second memory block being less than or equal to a retention time of another memory block in the memory device whose programming has been completed; 2.2, the program temperature of the second memory block being within the preset temperature range; and 2.3, a duration in which programming of the second memory block has been completed reaching a fourth preset duration.

For example, the second preset requirement comprises: \textcircled{1} retention time being less than 3 days, and retention time is minimum among all close blks, \textcircled{2} program temperature being between [68, 140] ° F. ([20, 60] ° C.), and \textcircled{3} close time being greater than 10 mins.

In response to absence of a memory block that meets the second preset requirement in the memory device 104, the first memory block is used as a memory block for which the retention time is adjusted. That is, when the first memory block fails to match the first preset requirement, the memory controller 106 searches the second memory block according to the second preset requirement, and if there is no second memory block that meets the second preset requirement in the memory device 104, continues to use the first memory block as the memory block for which the retention time is adjusted, that is, continues to obtain the first voltage offset group of the first memory block.

In some examples, during operation of the memory system 102, the second voltage offset group of the first memory block is obtained periodically; a latest obtained second voltage offset group is written to the memory device 104 in response to the memory system 102 being powered down; and the second voltage offset group is read from the memory device 104 in response to the memory system 102 being powered on.

In some examples, during operation of the memory system 102, a read operation is performed on the first memory block by using at least two candidate voltage offset groups to obtain read results of the at least two candidate voltage offset groups, and a second voltage offset group is determined based on the read results and the at least two candidate voltage offset groups.

In some examples, a voltage valley is searched for the first memory block to obtain a first voltage offset group.

In some examples, when the memory system 102 is powered down, the memory block identifier of the first memory block, the second voltage offset group, or the second voltage offset corresponding to the second voltage offset group, and the retention time of the first memory block are stored in the memory device 104.

After obtaining the second voltage offset group, a power failure event occurs in the memory system 102, and the first voltage offset group is an offset group obtained for the first memory block and used to express a plurality of threshold voltage distribution offsets in the first memory block when the memory system 102 is powered on again after powered down. That is, there is at least the power failure time of the memory system 102 between the obtaining of the first voltage offset group and the obtaining of the second voltage offset group.

After the memory system 102 is powered on, the first voltage offset group corresponding to the first memory block is obtained. In some examples, the memory block corresponding to the second voltage offset group obtained when the memory system is powered down is first determined, that is, the first memory block, and then the second voltage offset group corresponding to the first memory block is obtained. In some examples, when the second voltage offset group is stored, the memory block identifier of the memory block corresponding to the second voltage offset group is correspondingly stored, and the memory block identifier comprises at least one of a memory block address, a memory block number, and the like.

In some examples, the first voltage offset group is obtained in a preset phase in which the memory system 102 is powered on.

In some examples, the obtaining manner of the first voltage offset group refers to the obtaining manner of the second voltage offset group, and details are not described herein again.

Taking a solid state drive SSD as an example, in some examples of the present disclosure, a first voltage offset group is obtained in a power-on initialization process of the SSD.

In some examples, during the power-on initialization process of the memory system 102, the voltage valley is searched for the first memory block to obtain the first voltage offset group.

Operation 920: adjusting a retention time corresponding to at least one memory block in the memory device based on the first voltage offset group and the second voltage offset group.

In some examples, the power failure time of the memory system 102 is predicted based on the first voltage offset group and the second voltage offset group, and the power failure time is added to all the valid memory blocks (valid blk) of the memory device 104, wherein the valid memory block refers to a memory block to which data has been written and corresponds to a retention time.

In conclusion, in the control method of the memory system provided in some examples of the present disclosure, when the memory system is powered down and powered on again, the first voltage offset group of the first memory block is obtained, so that the power failure time of the memory system is predicted through the first voltage offset group and the second voltage offset group obtained before powered down, and the power failure time is added to the retention time of the memory block, the retention time of the memory block is adjusted, which improves the accuracy of recording the retention time of the memory block, thereby improving the timeliness and accuracy of the memory system when performing the reliability actions on the memory block based on the retention time, and improving the running stability of the memory system.

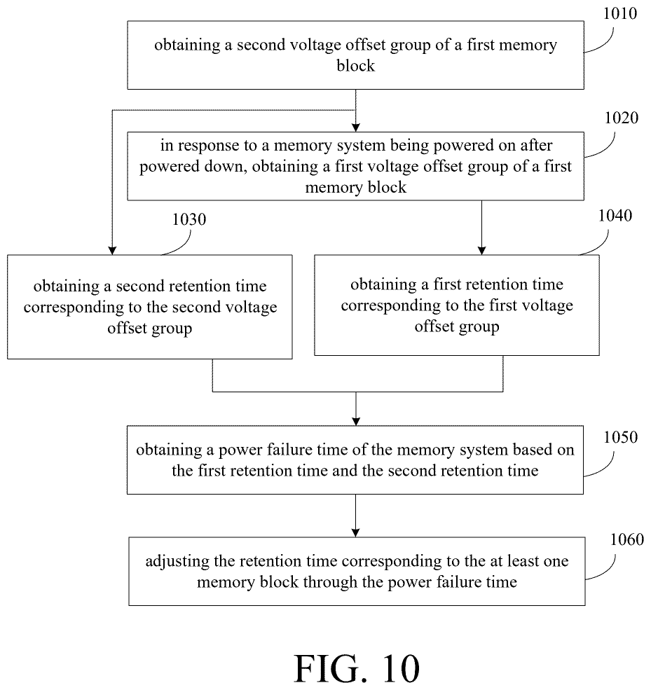

FIG. 10 is a flowchart of a control method of a memory system according to some examples of the present disclosure. The memory system 102 provided by the present disclosure includes a memory device 104 and a memory controller 106. In some examples, the memory system 102 comprises a solid state drive SSD. In some examples, the memory device 104 comprises a trinary-level cell TLC.

The control method of the memory system is performed by the memory controller 106. The method comprises the following operations 1010 to 1060.

Operation 1010: obtaining a second voltage offset group of the first memory block.

In some examples, during operation of the memory system 102, the second voltage offset group of the first memory block is periodically obtained and stored in the buffer. When a power failure event occurs in the memory system 102, the latest obtained second voltage offset group is written into the memory device 104 for use by the memory system 102 after being powered on again.

In some examples, the memory controller 106 comprises a buffer 701, and the buffer 701 is configured to buffer the voltage offset group or the voltage offset collected in this example.

In some examples, the second voltage offset group is an offset group that is obtained for the first memory block and that is used to express a plurality of threshold voltage distribution offsets in the first memory block during operation of the memory system 102, that is, obtain a differentiated voltage of a plurality of threshold voltage distributions in the first memory block, the differentiated voltage is offset relative to a differentiated voltage after the first memory block is programmed, and the second voltage offset group is used to express the offset.

Operation 1020: obtaining a first voltage offset group of a first memory block in response to the memory system being powered on after powered down.

After obtaining the second voltage offset group, a power failure event occurs in the memory system 102, and the first voltage offset group is an offset group obtained for the first memory block and used to express a plurality of threshold voltage distribution offsets in the first memory block when the memory system 102 is powered on again after powered down. That is, there is at least the power failure time of the memory system 102 between the obtaining of the first voltage offset group and the obtaining of the second voltage offset group.

Operation 1030: obtaining a second retention time corresponding to the second voltage offset group.

In some examples, operation 1030 may be performed before operation 1020, when the memory system is powered down, a second retention time corresponding to the second voltage offset group is obtained, and the second retention time is stored in the memory device 104. Alternatively, operation 1030 may also be performed after the memory system is powered on, for example, after operation 1020, after the first voltage offset group is obtained, a second retention time corresponding to the second voltage offset group is determined.

In some examples, a second voltage offset corresponding to the first program state is obtained from the second voltage offset group, and a second retention time corresponding to the second voltage offset is obtained.

In some examples, the second retention time is determined based on the number of historical erasing times of the first memory block and the second voltage offset.

Operation 1040: obtaining a first retention time corresponding to the first voltage offset group.

In some examples, a first voltage offset corresponding to the first program state is obtained from the first voltage offset group, and a first retention time corresponding to the first voltage offset is obtained.

In some examples, the first retention time is determined based on the number of historical erasing times of the first memory block and the first voltage offset.

Operation 1050: obtaining a power failure time of the memory system based on the first retention time and the second retention time.

In some examples, when the first retention time is determined based on the first voltage offset, the first retention time is calculated by the preset fitting formula and the first voltage offset.

In some examples, since the data retention capability is related to the number of erasing times of the flash memory, the greater the number of erasing times, the worse the data retention capability and the shorter the data retention period. Therefore, the first retention time is determined based on the number of historical erasing times and the first voltage offset of the first memory block, and the second retention time is determined based on the number of historical erasing times and the second voltage offset.

For example, the fitting formula between the voltage offset and the retention time is as follows:

PE 0-1K: y=a₁x²−b₁x+c₁; (1)

PE 1-3K: y=a₂x²−b₂x+c₂; (2)

PE 3-7K: y=a₃x²−b₃x+c₃; (3)

PE≥7K: y=a₄x²−b₄x+c₄. (4)

Wherein a₁, b₁, c₁, a₂, b₂, c₂, a₃, b₃, c₃, a₄, b₄, c₄ is a preset known parameter, and the four fitting formulas are different.

Wherein PE 0-1K refers to that the number of historical erasing times is in a range of 0 to 1000, including 0 and excluding 1000, PE 1-3K refers to that the number of historical erasing times is in a range of 1000 to 3000, including 1000 and excluding 3000, PE 3-7K refers to that the number of historical erasing times is in a range of 3000 to 7000, including 3000 and excluding 7000, and PE≥7K refers to that the number of historical erasing times is in the range of greater than or equal to 7000.

In some examples, the number of historical erasing times of the first memory block is stored in a specified memory location corresponding to the first memory block, the number of historical erasing times of the first memory block is obtained from the specified memory location corresponding to the first memory block, and the first retention time corresponding to the first voltage offset of the first memory block is calculated based on the fitting formula corresponding to the number of historical erasing times.

It should be noted that the range of the number of historical erasing times corresponding to the fitting formula above is merely illustrative, and the range of the number of historical erasing times corresponding to the fitting formula may be divided by other dividing granularities, for example, 0-1K, 1-2K, 2-3K, and so on, and the manner of dividing the range of the number of historical erasing times is not limited in some examples of the present disclosure. In addition, a formula form of the fitting formula is merely an example, and the fitting formula may also be implemented as a third-order formula, a prescribing formula, or any other form of formula, and a formula form of the fitting formula is not limited in some examples of the present disclosure.

The corresponding fitting formula is used for calculation according to the number of historical erasing times of the first memory blocks. For example, if the number of historical erasing times of the first memory block is 3200, the retention time corresponding to the first voltage offset and the second voltage offset is calculated by using the formula (3). x corresponds to the voltage offset, and y is the calculated retention time. The first voltage offset is substituted as the value of x into the formula (3) to obtain the first retention time rttTime1, and the second voltage offset is substituted as the value of x into the formula (3) to obtain the second retention time rttTime2, and the power failure time is calculated and obtained as tPowerOff=rttTime1−rttTime2.

In operation 1060, the retention time corresponding to the at least one memory block is adjusted by the power failure time.

In conclusion, in the control method of the memory system provided in some examples of the present disclosure, when the memory system is powered down and powered on again, the first voltage offset group of the first memory block is obtained, so that the power failure time of the memory system is predicted through the first voltage offset group and the second voltage offset group obtained before powered down, and the power failure time is added to the retention time of the memory block, the retention time of the memory block is adjusted, which improves the accuracy of recording the retention time of the memory block, thereby improving the timeliness and accuracy of the memory system when performing the reliability actions on the memory block based on the retention time, and improving the running stability of the memory system.

An example of the present disclosure provides an electronic device, comprising the memory system 102 according to any one of the foregoing examples, and a host 108 coupled to the memory system 102. The electronic device may be a mobile phone, a desktop computer, a laptop computer, a tablet computer, a vehicle computer, a game console, a printer, a pointing device, a wearable electronic device, a smart sensor, a virtual reality device, an augmented reality device, or the like.

An example of the present disclosure provides a computer-readable storage medium storing at least one computer program, wherein the at least one computer program is loaded and executed by a processor to implement the control method of the memory system according to any one of the foregoing examples. In some examples, the computer-readable storage medium is a non-transitory readable storage medium. For example, the at least one computer program is stored in the memory device 104 of the solid state drive SSD, and runs in a tightly coupled memory (TCM) of the memory controller 106 of the solid state drive SSD or in a cache of the memory controller 106, and is executed by a processor of the memory controller 106 of the solid state drive SSD to implement the control method of the memory system according to any one of the foregoing examples.

An example of the present disclosure provides a computer program stored in a computer-readable storage medium. The processor reads, from the computer-readable storage medium, the computer program which is to be loaded and executed by the processor to implement the control method of the memory system provided in the foregoing method examples.

In the present disclosure, the terms “first” and “second” are for illustrative purposes only and are not to be construed as indicating or implying relative importance. The term “at least one” refers to one or more, and the term “a plurality of” refers to two or more unless specifically defined otherwise.

The term “and/or” in the present disclosure is merely an association relationship for describing an associated object, it indicates that there may be three relationships, for example, A and/or B, which may indicate that only A is present, both A and B are present, and only B is present. In addition, the character “/” herein generally indicates that the front-back associated object is a “or” relationship.

The present disclosure provides a memory system, a device, a controller, a control method and a storage medium. The technical solution is as follows:

In an aspect, a memory system is provided, comprising: a memory device and a memory controller. The memory device comprises a plurality of memory blocks. The memory controller is configured to: obtain a first voltage offset group of a first memory block in response to the memory system being powered on after powered down and adjust a retention time corresponding to at least one memory block in the memory device based on the first voltage offset group and a second voltage offset group. The second voltage offset group is a voltage offset group of the first memory block obtained before the memory system is powered down.

In some examples, the first memory block meets a first preset requirement, the first preset requirement comprises: a retention time of the first memory block being less than a first preset duration, a program temperature being within a preset temperature range, and a duration in which programming of the first memory block has been completed reaching a second preset duration.

In some examples, the memory controller is further configured to: in response to the first memory block failing to match the first preset requirement, determine a second memory block meeting a second preset requirement; obtain a third voltage offset group of the second memory block in response to a memory system being powered on after powered down; and adjust the retention time corresponding to the at least one memory block in the memory device based on the third voltage offset group and a fourth voltage offset group. The fourth voltage offset group is a voltage offset group of the second memory block obtained before the memory system is powered down.

In some examples, the second preset requirement comprises: a retention time of the second memory block being less than a third preset duration, and the retention time of the second memory block being less than or equal to a retention time of another memory block whose programming has been completed in the memory device, a program temperature being within the preset temperature range, and a duration in which programming of the second memory block has been completed reaching a fourth preset duration.

In some examples, the memory controller is further configured to: in response to there being no memory block that meets the second preset requirement in the memory device, use the first memory block as a memory block for which the retention time is adjusted.

In some examples, the memory controller is further configured to: during operation of the memory system, obtain the second voltage offset group of the first memory block periodically; write a latest obtained second voltage offset group to the memory device in response to the memory system being powered down; and read the second voltage offset group from the memory device in response to the memory system being powered on after powered down.

In some examples, the memory controller is further configured to: during operation of the memory system, perform a read operation on the first memory block by at least two candidate voltage offset groups to obtain read results of the at least two candidate voltage offset groups; and determine the second voltage offset group based on the read results and the at least two candidate voltage offset groups.

In some examples, the memory controller is further configured to: obtain a first voltage offset corresponding to a first program state from the first voltage offset group; and obtain a second voltage offset corresponding to the first program state from the second voltage offset group.

In some examples, the memory controller is further configured to: obtain a first retention time corresponding to the first voltage offset; obtain a second retention time corresponding to the second voltage offset; obtain a power failure time of the memory system based on the first retention time and the second retention time; and adjust the retention time corresponding to the at least one memory block through the power failure time.

In some examples, the memory controller is further configured to: determine the first retention time based on a number of historical erasing times of the first memory block and the first voltage offset; and determine the second retention time based on the number of historical erasing times and the second voltage offset. In some examples, the memory system comprises a solid state drive SSD.

In another aspect, a memory controller is provided, comprising a buffer configured to buffer a voltage offset or a voltage offset group and one or more processors. The one or more processors is configured to: obtain a first voltage offset group of a first memory block in response to a memory system being powered on after powered down; and adjust a retention time corresponding to at least one memory block in a memory device based on the first voltage offset group and a second voltage offset group. The second voltage offset group is a voltage offset group of the first memory block obtained before the memory system is powered down.

In another aspect, an electronic device is provided, comprising: the memory system according to any one of the above examples; and a host coupled to the memory system.

In another aspect, a control method of a memory system is provided, comprising: obtaining a first voltage offset group of a first memory block in response to the memory system being powered on after powered down; and adjusting a retention time corresponding to at least one memory block in a memory device based on the first voltage offset group and a second voltage offset group. The second voltage offset group is a voltage offset group of the first memory block obtained before the memory system is powered down.

In some examples, the first memory block meets a first preset requirement, the first preset requirement comprises: a retention time of the first memory block being less than a first preset duration, a program temperature being within a preset temperature range, and a duration in which programming of the first memory block has been completed reaching a second preset duration.

In some examples, the method further comprises: in response to the first memory block failing to match the first preset requirement, determining a second memory block meeting a second preset requirement; obtaining a third voltage offset group of the second memory block in response to the memory system being powered on after powered down; and adjusting the retention time corresponding to the at least one memory block in the memory device based on the third voltage offset group and a fourth voltage offset group. The fourth voltage offset group is a voltage offset group of the second memory block obtained before the memory system is powered down.

In some examples, the second preset requirement comprises: a retention time of the second memory block being less than a third preset duration, a program temperature being within the preset temperature range, and a duration in which programming of the second memory block has been completed reaching a fourth preset duration. The retention time of the second memory block being less than or equal to a retention time of another memory block whose programming has been completed in the memory device.

In some examples, the method further comprises: in response to the absence of a memory block that meets the second preset requirement in the memory device, using the first memory block as a memory block for which the retention time is adjusted.

In some examples, the method further comprises: during operation of the memory system, obtaining the second voltage offset group of the first memory block periodically; writing a latest obtained second voltage offset group to the memory device in response to the memory system being powered down; and reading the second voltage offset group from the memory device in response to the memory system being powered on after powered down.

In some examples, the method further comprises: during operation of the memory system, performing a read operation on the first memory block by at least two candidate voltage offset groups to obtain read results of the at least two candidate voltage offset groups; and determining the second voltage offset group based on the read results and the at least two candidate voltage offset groups.

In some examples, the method further comprises: obtaining a first voltage offset corresponding to a first program state from the first voltage offset group; and obtaining a second voltage offset corresponding to the first program state from the second voltage offset group.

In some examples, the adjusting the retention time corresponding to the at least one memory block based on the first voltage offset and the second voltage offset comprises: obtaining a first retention time corresponding to the first voltage offset; obtaining a second retention time corresponding to the second voltage offset; obtaining a power failure time of the memory system based on the first retention time and the second retention time; and adjusting the retention time corresponding to the at least one memory block through the power failure time.

In some examples, the obtaining the first retention time corresponding to the first voltage offset comprises: determining the first retention time based on a number of historical erasing times of the first memory block and the first voltage offset; and the obtaining the second retention time corresponding to the second voltage offset comprises: determining the second retention time based on the number of historical erasing times and the second voltage offset.

In some examples, the memory system comprises a solid state drive SSD.

In another aspect, a non-volatile readable storage medium is provided, wherein the storage medium stores at least one computer program, and the at least one computer program is loaded and executed by a processor to implement the control method of the memory system according to any one of the above examples.

The technical solutions provided in the present disclosure may comprise the following beneficial effects: when the memory system is powered down and powered on again, the first voltage offset group of the first memory block is obtained, so that the power failure time of the memory system is predicted through the first voltage offset group and the second voltage offset group obtained before powered down, and the power failure time is added to the retention time of the memory block, the retention time of the memory block is adjusted, which improves the accuracy of recording the retention time of the memory block, thereby improving the timeliness and accuracy of the memory system when performing the reliability actions on the memory block based on the retention time, and improving the running stability of the memory system.

The above descriptions are merely examples of the present disclosure, and are not intended to limit the present disclosure, and any modifications, equivalent substitutions and improvements made within the spirit and principle of the present disclosure should be comprised within the protection scope of the present disclosure.

What is claimed is:

1. A memory system, comprising:
a memory device comprising a plurality of memory blocks; and
a memory controller configured to:
in response to the memory system being powered on after the memory system is powered down, obtain a first voltage offset group of a first memory block; and
adjust a retention time corresponding to at least one memory block of the plurality of memory blocks based on the first voltage offset group and a second voltage offset group, wherein the second voltage offset group is of the first memory block and is obtained before the memory system is powered down.

2. The memory system of claim 1, wherein the retention time is a first retention time, determining whether the first memory block satisfies first conditions, the first conditions comprising:
a second retention time of the first memory block being less than a first duration,
a program temperature being within a temperature range, and
a second duration of programming of the first memory block satisfying a third duration.

3. The memory system of claim 2, wherein the memory controller is configured to:
in response to the first memory block failing to satisfy the first conditions, determine a second memory block satisfying second conditions;
in response to the memory system being powered on after the memory system is powered down, obtain a third voltage offset group of the second memory block; and
adjust the first retention time corresponding to the at least one memory block based on the third voltage offset group and a fourth voltage offset group, wherein the fourth voltage offset group is of the second memory block and is obtained before the memory system is powered down.

4. The memory system of claim 3, wherein the second conditions comprise:
a third retention time of the second memory block being less than a fourth duration, and the second retention time of the second memory block being less than or equal to a fourth retention time of a third memory block in the memory device for which programming has been completed in the memory device,
the program temperature being within the temperature range, and
a fifth duration of programming of the second memory block satisfying a sixth duration.

5. The memory system of claim 3, wherein the memory controller is configured to:
in response to absence of the second memory block that satisfies the second conditions, use the first memory block as a memory block for which the first retention time is adjusted.

6. The memory system of claim 1, wherein the memory controller is configured to:
during operation of the memory system, obtain the second voltage offset group of the first memory block periodically;
in response to the memory system being powered down, write a latest obtained second voltage offset group to the memory device; and
in response to the memory system being powered on after the memory system is powered down, read the latest obtained second voltage offset group from the memory device.

7. The memory system of claim 1, wherein the memory controller is configured to:
during operation of the memory system, perform a read operation on the first memory block by at least two candidate voltage offset groups to obtain read results of the at least two candidate voltage offset groups; and
determine the second voltage offset group based on the read results and the at least two candidate voltage offset groups.

8. The memory system of claim 1, wherein the memory controller is configured to:
obtain a first voltage offset corresponding to a first program state from the first voltage offset group; and
obtain a second voltage offset corresponding to the first program state from the second voltage offset group.

9. The memory system of claim 8, wherein the retention time is a first retention time, the memory controller is configured to:
obtain a second retention time corresponding to the first voltage offset;
obtain a third retention time corresponding to the second voltage offset;
obtain a power failure time of the memory system based on the second retention time and the third retention time; and
adjust the first retention time corresponding to the at least one memory block based on the power failure time.

10. The memory system of claim 9, wherein the memory controller is configured to:
determine the second retention time based on a number of historical erase times of the first memory block and the first voltage offset; and
determine the third retention time based on the number of historical erase times and the second voltage offset.

11. The memory system of claim 1, wherein
the memory system comprises a solid state drive (SSD).

12. A memory controller, comprising:
a buffer configured to buffer a voltage offset or a voltage offset group;
one or more processor circuits configured to:
in response to a memory system being powered on after the memory system is powered down, obtain a first voltage offset group of a first memory block; and
adjust a retention time corresponding to at least one memory block in a memory device based on the first voltage offset group and a second voltage offset group, wherein the second voltage offset group is of the first memory block and is obtained before the memory system is powered down.

13. A method, comprising:
in response to a memory system being powered on after the memory system is powered down, obtaining a first voltage offset group of a first memory block; and
adjusting a retention time corresponding to at least one memory block in a memory device based on the first voltage offset group and a second voltage offset group, wherein the second voltage offset group is of the first memory block and is obtained before the memory system is powered down.

14. The method of claim 13, wherein the retention time is a first retention time, the method further comprising determining whether the first memory block satisfies first conditions which comprise:
a second retention time of the first memory block being less than a first duration,
a program temperature being within a temperature range, and
a second duration of programming of the first memory block satisfies a third duration.

15. The method of claim 14, further comprising:
in response to the first memory block not satisfying the first conditions, determining a second memory block that satisfies second conditions;
in response to the memory system being powered on after the memory system is powered down, obtaining a third voltage offset group of the second memory block; and
adjusting the first retention time corresponding to the at least one memory block based on the third voltage offset group and a fourth voltage offset group, wherein the fourth voltage offset group is of the second memory block and is obtained before the memory system is powered down.

16. The method of claim 15, wherein the second conditions comprise:
a third retention time of the second memory block being less than a fourth duration, and the third retention time of the second memory block being less than or equal to a fourth retention time of another memory block for which programming has been completed in the memory device,
the program temperature being within the temperature range, and
a fifth duration of programming of the second memory block satisfies a sixth duration.

17. The method of claim 15, further comprising:
in response to absence of the second memory block that satisfies the second conditions, using the first memory block as a memory block for which the retention time is adjusted.

18. The method of claim 13, further comprising:
during operation of the memory system, obtaining the second voltage offset group of the first memory block periodically;
in response to the memory system being powered down, writing a latest obtained second voltage offset group to the memory device; and
in response to the memory system being powered on after the memory system is powered down, reading the latest obtained second voltage offset group from the memory device.

19. The method of claim 13, further comprising:
during operation of the memory system, performing a read operation on the first memory block by at least two candidate voltage offset groups to obtain read results of the at least two candidate voltage offset groups; and
determining the second voltage offset group based on the read results and the at least two candidate voltage offset groups.

20. The method of claim 13, further comprising:
obtaining a first voltage offset corresponding to a first program state from the first voltage offset group; and
obtaining a second voltage offset corresponding to the first program state from the second voltage offset group.
